(19) United States
(12) Patent Application Publication
(10) Pub. No.: US 2019/0235012 A1
(43) Pub. Date: Aug. 1, 2019

(54) METHOD AND ARRANGEMENT FOR LOCALISING INTERFERENCE IN ELECTRICAL DISTRIBUTION SYSTEMS

(71) Applicant: E.ON SE, Essen (DE)

(72) Inventors: Malte Knizia, Pentenried (DE); Marcus Siepe, Kaarst (DE)

(21) Appl. No.: 16/312,073

(22) PCT Filed: Jun. 15, 2017
(86) PCT No.: PCT/EP2017/064655

§ 371 Date: Dec. 20, 2018

(30) Foreign Application Priority Data
Jun. 27, 2016 (EP) 16176487.3

(51) Int. Cl. G01R 31/08

(52) U.S. Cl. CPC G01R 31/086

(57) ABSTRACT

The invention relates to a method and to an arrangement for the local delimitation of faults in distribution networks (1), in particular in electrical distribution networks.

Method for the local delimitation of faults (X) in an electrical distribution network (1) with a receiver unit (9.1, 9.2, 9.3) comprising a position determination module and with a database (12) comprising position information about devices (4.1-4.11), connected to the distribution network (1), which transmit radio signals identifiable by the receiver unit (9.1, 9.2, 9.3) and assignable to the respective device (4.1-4.11), comprising the steps of:
a. determining the active devices (4.1-4.11) located in the neighbourhood of the receiver unit (9.1, 9.2, 9.3) using the identifiable radio signals transmitted by these devices (4.1-4.11) and assignable to the respective device (4.1-4.11);
b. determining the position of the receiver unit (9.1, 9.2, 9.3) through the position determination module;
c. determining, from the database, devices (4.1-4.11) located in the neighbourhood of the receiver unit (9.1, 9.2, 9.3) on the basis of the determined position of the receiver unit (9.1, 9.2, 9.3);
d. determining the deactivated devices (4.1-4.11) in the neighbourhood of the receiver unit (9.1, 9.2, 9.3) through comparison of the active devices (4.1-4.11) determined with the determined devices (4.1-4.11) located in the neighbourhood of the receiver unit (9.1, 9.2, 9.3); and
e. delimiting the fault in the distribution network by evaluating the position information of the determined active and deactivated devices (4.1-4.11).

The arrangement according to the invention is designed for carrying out this method.

The invention relates to a method and to an arrangement for the local delimitation of faults in distribution networks, in particular electrical distribution networks.

The electric power generated by large power stations and decentralized energy generators is transported to the consumers over a supply network. To cover larger distances, the electric power is frequently here first routed over high or extra-high voltage networks before it is further distributed over medium-voltage networks. Individual industrial consumers can be connected directly even to the medium-voltage networks. The great majority of consumers however, private households in particular, obtain electric power over a low-voltage network downstream of the medium-voltage network.

As a rule, the high or extra-high voltage network and the medium-voltage network have equipment for monitoring the network at their disposal, and are closely observed in a control centre so that faults can be recognized promptly and rectified where appropriate. The network monitoring system here allows the position of a fault in the network to be localized accurately, in order either to take measures aimed directly at the site of the fault for rectifying the fault, or to isolate the site of the fault at least temporarily from the rest of the network, so that the fault does not propagate into other regions of the network.

No such detailed monitoring is usually provided in low-voltage networks. The operator of a low-voltage distribution network is, rather, frequently reliant on the report of a fault, for example of a power failure, by third parties such as end-customers, and can only then begin the search for the fault. In the best case, the operator is here already able, on the basis of one or a plurality of reports, to delimit a region of his distribution network in which the fault has a high probability of lying. If the operator receives a message that the power has failed at a user, the cause of the fault can namely be presumed initially to be in the conduction path from the point at which the electric power is fed into the low-voltage distribution network and the address of the user. A further localization of the fault is not, however, readily possible. The operator therefore must perform a costly search for the true site of the fault.

Methods and arrangements with which faults in a low-voltage distribution network can be localized more accurately are known from the prior art. The European patent application EP 2 806 572 A1 for example proposes an arrangement in which, through communication with and between intelligent electricity meters (“smart meters”) connected to the low-voltage distribution network, which takes place over the lines of the network, it can be established whether measurable signal attenuations or communication failures are occurring. The latter can supply an indication of the location of the fault.

It is disadvantageous in this prior art that it is essential that special electricity meters, namely intelligent electricity meters, must be provided for the localization of faults in distribution networks. The replacement of conventional electricity meters that are already present by intelligent electricity meters is extremely expensive and time-consuming, in particular for networks that already exist.

The invention is based on the object of creating a method and an arrangement for the local delimitation of faults in distribution networks, in which the known disadvantages of the prior art no longer occur or at least only do so to a reduced extent.

This object is achieved by a method according to the principal claim and to an arrangement according to the independent Claim 11. Advantageous developments are the objects of the dependent claims.

The invention accordingly relates to methods for the local delimitation of faults in an electrical distribution network with a receiver unit comprising a position determination module and with a database comprising position information about devices, connected to the distribution network, which transmit radio signals identifiable by the receiver unit and assignable to the respective device, with the steps of:
a. determining the active devices located in the neighbourhood of the receiver unit using the identifiable radio signals transmitted by these devices and assignable to the respective device;
b. determining the position of the receiver unit through the position determination module;
c. determining, from the database, devices located in the neighbourhood of the receiver unit on the basis of the determined position of the receiver unit;
d. determining the deactivated devices in the neighbourhood of the receiver unit through comparing the determined active devices with the devices determined to be located in the neighbourhood of the receiver unit; and
e. delimiting the fault in the distribution network by evaluating the position information of the determined active and deactivated devices.

The invention further relates to an arrangement for the local delimitation of faults in an electrical distribution network, comprising a receiver unit with a position determination module, a database comprising position information about devices, connected to the distribution network, which transmit radio signals identifiable by the receiver unit and assignable to the respective device, and a computer, where the computer is designed to determine from the database, with reference to the position determined by the position determination module of the receiver unit, devices located in the neighbourhood of the receiver unit, and to check, with reference to the radio signals received by the receiver unit, which of the devices determined in this way are active and which of the devices determined in this way are deactivated.

A few terms used in connection with the invention will first be explained in more detail:

In terms of the invention, radio signals transmitted by devices are “identifiable and assignable to the respective device” if at least one distinguishable identification feature which is suitable for assigning the radio signal to a single device as a unique source can be derived from a received radio signal. Thus, for example, radio signals repeatedly transmitted for identification (“Beacons”) by transmitters for digital radio networks (e.g. a “Wireless Local Area Network”, WLAN) regularly also have, in addition to an identifier of the network (“Service Set Identifier”, SSID), an identifier that identifies the transmitter or the device (“Media Access Control” address, MAC address), so that on reception of the radio signal one device can be uniquely identified as the transmitter. Comparable considerations apply to the signals of other radio networks, in particular digital radio networks.

A device is considered to be “active” if it transmits radio signals which, in principle, can be received by the receiver unit and which are identifiable and assignable to a device. A device is then considered to be “deactivated” if, while it is in principle suitable for transmitting corresponding radio signals in order to be counted as an active device in the sense of the invention, it does not however transmit any radio signals at the time when the method according to the invention is carried out. Apparatuses that cannot transmit any radio signals that are, in principle, identifiable and assignable, are not “devices” in the sense of the invention.

In the method according to the invention for delimiting faults in distribution networks, a comparison is made between the radio signals of devices that are indeed active received by the receiver unit and the, in principle, expected radio signals from devices located in the neighbourhood of the position of the receiver unit which are determined from a database in the light of the position of the receiver unit. The devices in the neighbourhood of the receiver unit that are deactivated can be determined from this comparison. The information regarding active and deactivated devices can be used in order to be able to delimit the location of the fault in the distribution network. The invention is based here on the fundamental principle that active devices connected to the distribution network will become deactivated due to the cessation of the power supply in the presence of a fault in the distribution network, e.g. a power failure, or the “tripping” of a circuit breaker.

The database used in the invention comprises position information about devices connected to the distribution network which are, in principle, capable of transmitting identifiable and assignable radio signals. The position information can here comprise particulars of the geographical position, for example in the form of geographical coordinates, and/or position in the network topology. “Position in the network topology” here refers to information from which the line of the distribution network to which a device is connected, or the line node of the distribution network through which the supply of electrical energy to the device is made, emerges unambiguously.

Yet further information about the individual devices can be stored in the database in addition to the position information. Devices are, for example, known that only transmit radio signals at certain times or during certain periods of time. A typical example of this is provided by WLAN access points in public facilities which are, for example, only active during the respective opening times. The database can contain information about the time-dependent activation and deactivation of at least some of the devices connected to the distribution network in order to ensure that a corresponding device, which is only active at certain times, and is determined to be deactivated in the method according to the invention is incorrectly deemed to be an indication of a possible fault in the network, although it was only deactivated in accordance with a predetermined schedule. It is thus possible to check for devices that are only active at certain times whether they are inactive as a result of the respective schedule or whether a determination of the device as deactivated could represent an indication from a fault in the network.

It is also possible that the database also contains information about whether devices connected to the distribution network have an uninterruptible power supply (UPS). Such devices with UPS in principle transmit radio signals that are understood by the receiver unit as an indication of an active device, at least for a certain period of time, even in the presence of a fault in the network and, for example, the cessation of the supply of electrical power over the distribution network. To avoid such a radio signal being understood as an indication of a functioning supply network even in the presence of a fault, corresponding information in the database can be helpful, so that devices with uninterruptible power supplies can be excluded where appropriate from the local delimitation of faults in the distribution network.

In the method according to the invention, the active devices located in the neighbourhood of the receiver unit are first determined, wherein this determination is made with reference to the radio signals transmitted by these active devices which can be identified by the receiver unit and can be assigned to the respective device. The determination can, for example, result in a list of devices located in the neighbourhood of the receiver unit and which are indeed active.

The position of the receiver unit is then determined by means of the position determination module associated with it. The position of the receiver unit can here be determined by methods known from the prior art. Thus, in addition to a determination of the position of the receiver unit through satellite navigation signals (e.g. GPS, Galileo or GLONASS), a position determination on the basis of radio signals that are identifiable by the receiver unit and assignable to a device is also possible. To the extent that the position of the devices whose radio signals are received is known, the approximate position of the receiver unit can be derived from this. The position of the devices in question can, for example, come from the previously described database. In particular when the receiver unit is a stationary unit, whose position is essentially unchanged, information about its position can also be stored in a memory from which the position determination module retrieves this information. The memory can here be directly assigned to the receiver unit or can be stored elsewhere in the form of a database, from which the position module can then call up the stored position, for example with the aid of a unique identifier of the receiver unit. It is also possible, in particular in the case of mobile receiver units, to store the most recently determined position in the memory regularly. The position stored in the memory can then be accessed if the requirement arises to determine the position of the receiver unit. This is in particular advantageous when a true position determination is not possible at the time of the requirement, for example because radio signals that can be evaluated are absent.

The position of the receiver unit can—similarly to the position of the devices—be represented in the form of geographical coordinates and/or as a position in the network topology. The way in which the position of the receiver unit is represented here depends in particular on the type of determination of the position of the receiver unit and on the design of the receiver unit as a mobile or stationary unit.

In particular when the position determination module for determining position does not make use of the received radio signals of the active devices, it is also possible for the determination of the position of the receiver module to take place in parallel with or in advance of the determination of the active devices located in the neighbourhood of the receiver unit.

When the position of the receiver unit has been determined, the devices located in the neighbourhood of the receiver unit are determined from the database on the basis of the determined position of the receiver unit. In other words, a determination is made through the database of which devices the receiver unit ought, in principle, to receive on the basis of its position, wherein—to the extent available—information about the time-dependent activation and deactivation of the devices can, of course, be taken into account.

Through a comparison of the devices located in the neighbourhood determined in this way and the previously determined active devices, the deactivated devices located in the neighbourhood of the receiver unit can be determined.

On the assumption that at least a significant proportion of the deactivated devices determined in this way are deactivated as a result of a fault in the network, the location of a fault in the distribution network can usually already be delimited through an evaluation of the position information originating from the database of the determined active and deactivated devices:
If the receiver unit does not receive a radio signal from a device connected to the distribution network, or only receives radio signals of corresponding devices with uninterruptible power supplies, it is possible to conclude from this that all the lines of the distribution network located in the neighbourhood of the receiver unit are affected by a fault. This can indicate, depending on the topology of the network, that the fault is present in a common line upstream of the lines located in the neighbourhood of the receiver unit.
If the receiver unit receives radio signals from all the devices located in the neighbourhood according to the database, the lines located in the neighbourhood of the receiver unit are probably not affected by the fault in the distribution network. Depending on the network topology, it can also be concluded from this that a common line upstream of the said lines is free from fault.
If the receiver unit only receives radio signals from a proportion of the devices located, according to the database, in the neighbourhood, it may be presumed that at least a large proportion of the devices determined to be deactivated are subject to the fault in the distribution network. Since another proportion of the devices located in the neighbourhood is clearly active at the same time, a boundary between a fault-free region of the network and a part of the network affected by the fault can be determined.

It is of no real significance here whether the position information of devices in the database is present in the form of geographical position information or of positions in the network topology. With sufficient knowledge of the network topology, including the position of the lines, the position information can, if required, be converted with sufficient precision from one form into the other.

It is preferred for the database to contain position information for devices not connected to the distribution network which transmit radio signals that are identifiable by the receiver unit and assignable to the respective device. Inasmuch as the position determination of the receiver unit takes place on the basis of received radio signals, a position determination is then also still possible if all the devices that are located in the neighbourhood and connected to the supply network are deactivated, for example as a result of a fault in the network. Battery-operated devices such as, for example, wireless window contacts of a heating controller or an alarm installation, radio thermostats etc. are examples of devices not connected to the distribution network.

The devices connected to the distribution network can preferably comprise the network operator's own devices such as, for example, electricity meters and/or distribution boxes. Corresponding devices offer the advantage that they directly have a unique position in the network topology which can simplify the local delimitation of faults.

The receiver unit can be an (intelligent) electricity meter or a mobile terminal, in particular a so-called smartphone or tablet, which preferably can communicate over a mobile radio network. If the receiver unit is an electricity meter, it preferably has a communication module for transmitting and receiving data. It is to be borne in mind here that—in contrast to the prior art—it is not necessary for all the electricity meters of a distribution network to be electricity meters fitted out in this way.

If the receiver unit is a mobile telephone, the battery charge status and/or the light impinging on a camera of the mobile telephone can also be taken into account in the delimitation of the fault in the distribution network as additional information about the status of the distribution network in the region of the receiver unit. If the mobile telephone establishes that a charging process changes suddenly, for example is interrupted, it can be presumed that the line to which the charging device of the mobile telephone is connected is affected by a fault of the supply network. If, during the night, a significant light incidence is established in the camera, it can be presumed that at least the supply of the electric light via the supply network is not affected by a fault.

It is, in principle, possible for the database to be arranged immediately at the receiver unit. It is, however, preferred for the database to be maintained separately from the receiver unit. This offers the advantage that the database can be used simultaneously by a plurality of receiver units, and it is possible to more easily ensure that the database used by a receiver unit is up-to-date. The communication between the receiver unit and the database can here preferably take place over a mobile radio network, at least in the event of failure of other communication routes, for example over the distribution network itself. The components of a mobile radio network usually incorporate an emergency power supply, so that the mobile radio network usually continues to be available even when the supply network fails. The determination of devices, or of the deactivated devices, located in the neighbourhood of the receiver unit can be carried out by the receiver unit, by the database, or by a computer linked to the database and the receiver unit. An appropriate computer can, for example, be provided in the control centre of the network operator.

It is preferable if the database is self-learning, and information relating to the connection to the distribution networks and/or an uninterruptible power supply of individual devices is preferably updated as required. If, for example, it is established during a failure of a line of the supply network that the radio signals of a device connected thereto only cease after a time delay or not at all, it can be presumed that this device has an uninterruptible power supply. If the radio signal of an entirely unknown device is identified, it can basically be concluded that a new device has been connected to the distribution network. The database can be correspondingly extended, wherein the position information can initially be estimated in an automated manner depending on the position of the receiver unit, and made more precise in the course of time, for example in that each time a radio signal is received from this device, a check is made as to whether its position information can basically be correct or not. In the latter case, the position information is systematically modified. It remains, of course, possible, even for a self-learning database, for individual devices to be recorded or for their data records to be updated manually.

The radio signals that can be identified by the receiver unit and assigned to a device are preferably WLAN, Bluetooth, Zigbee, Z-Wave and/or EnOcean signals.

Reference is made to the above explanations for explanation of the arrangement according to the invention.

The invention is now described by way of example with reference to an advantageous exemplary embodiment and with reference to the appended drawings. Here:

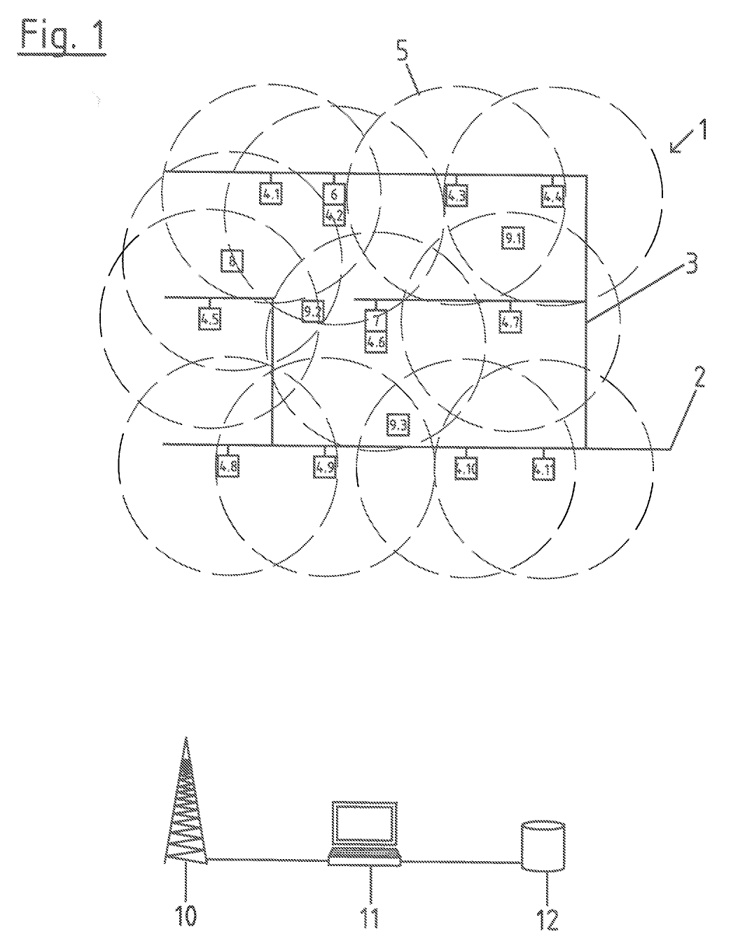

FIG. 1: shows a first exemplary embodiment of an arrangement according to the invention with a supply network in the state without fault; and

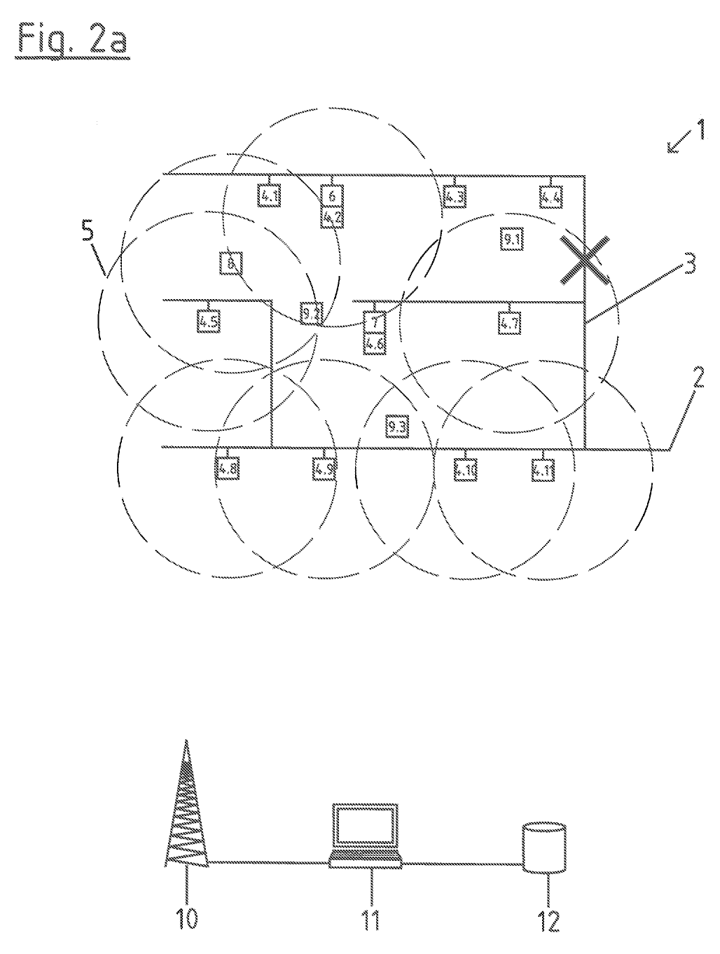

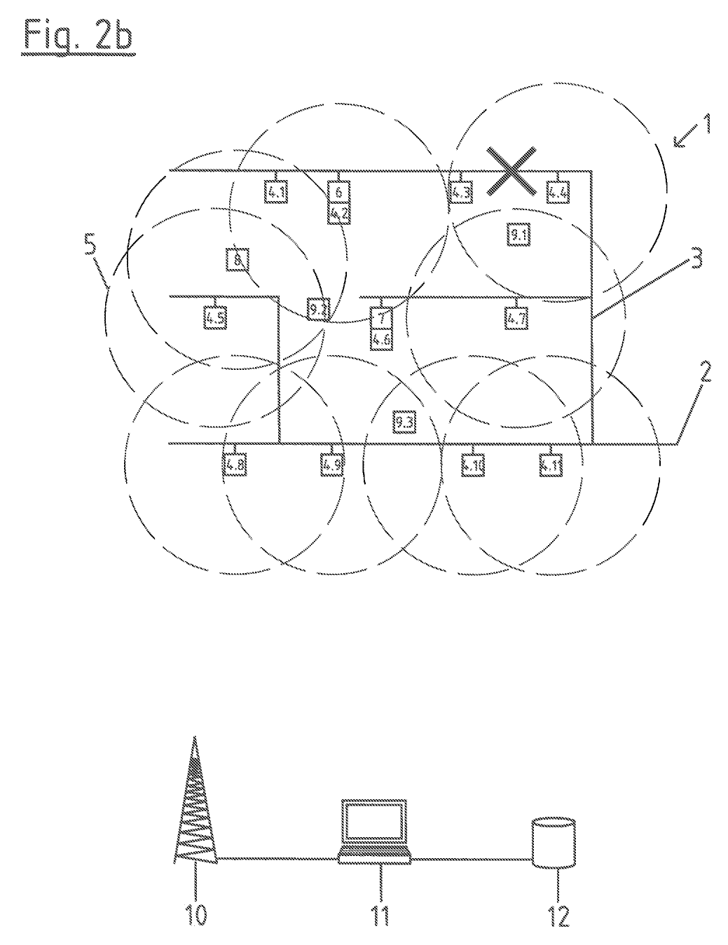

FIGS. 2a-b: show various network states of the arrangement of FIG. 1.

An electrical distribution network 1 is illustrated schematically in FIG. 1, being connected to an upstream network (not illustrated) at the connection point 2, and distributes the electrical line leading from there over a branched supply network 3.

A plurality of devices 4.1 to 4.11 are connected to the distribution network 1, each of which, when in the active state, emits a radio signal identifiable by one of the receiver units 9.1 to 9.3, which are explained further below, and which can be unambiguously assigned to a device 4.1-4.11. The range of the respective radio signal is suggested by the dotted circles around the respective devices 4.1-4.11. The device 4.2 has an uninterruptible power supply 6, so that even when the distribution network 1 fails, it can still continue to be operated. The device 4.6 is connected to the distribution network 1 through a timer switch 7, and is only active between the times of 09:00 and 17:00.

In addition to this, a further device 8 is provided which, while it also transmits identifiable and assignable radio signals, is however operated with a battery entirely independently of the distribution network 1.

Three receiver units 9.1, 9.2 and 9.3 are also drawn in FIG. 1 in the region of the distribution network 1. These receiver units 9.1, 9.2 and 9.3 are mobile telephones or smartphones that are designed to receive the radio signals transmitted by the devices 4.1-4.11, 8 when in the active state, and which, moreover, have a position determination module (not illustrated) for determining the position of the respective receiver units 9.1, 9.2, 9.3. The receiver units 9.1, 9.2 and 9.3 also have a communication module, so that data relating to the position of the receiver unit 9.1, 9.2, 9.3 and the radio signals received by the receiver unit 9.1, 9.2, 9.3 via a mobile radio network suggested by a mobile radio mast can be transmitted to a computer 11. The computer 11 furthermore has access to a database 12.

Position information on all the devices 4.1-4.11, 8 is registered in the database 12, where the information comprises both particulars of the geographical position in the form of geographical coordinates as well as details on the position in the network topology—i.e. to which line 3 in the supply network 1 the respective device 4.1-4.11, 8 is connected. The fact that device 4.2 has an uninterruptible power supply 6, that device 4.6 is only switched on at certain times of day, and that device 8 is battery-operated, is also noted in the database 12.

A receiver unit 9.1, 9.2, 9.3 regularly, on establishing a sudden cessation of one or more radio signals, or in response to an explicit command of a user, transmits the information over the mobile radio network 10 to the computer 11 relating to the received radio signals, with reference to which the devices 4.1-4.11, 8 are identifiable, and the individual radio signals are uniquely assignable to an individual device 4.1-4.11, 8. At the same time, the receiver units 9.1, 9.2, 9.3 also transmit the position of the receiver unit 9.1, 9.2, 9.3 determined by their respective position determination module. In the present exemplary embodiment, the position determination is performed by means of GPS signals, while the precision of the position determination can be increased in the known manner through the evaluation of WLAN signals which can, for example, involve radio signals transmitted by the devices 4.1-4.11, 8. The position of the receiver unit 9.1, 9.2, 9.3 is determined in geographical coordinates.

On the basis of the position obtained from a receiver unit 9.1, 9.2, 9.3 the computer 11 can determine, with reference to the database 12, which devices 4.1-4.11, 8 are essentially located in the neighbourhood of the respective receiver unit 9.1, 9.2, 9.3. It is, in other words, possible to determine the devices 4.1-4.11, 8 from which a receiver unit 9.1, 9.2, 9.3 should in principle receive radio signals, bearing in mind the respective range 5, provided the devices 4.1-4.11, 8 are active. In the exemplary embodiment illustrated these are, for the receiver unit 9.1 for example the devices 4.3, 4.4 and 4.7, for the receiver unit 9.2 the devices 4.1, 4.2, 4.5, 4.6 and 8, and for the receiver unit 9.3 the devices 4.6, 4.9 and 4.10.

In the state of the supply network 1 with no faults illustrated in FIG. 1, all the devices 4.1-4.11, 8 are active, and thus transmit radio signals which—provided they are located within the respective range 5—can be received by the receiver units 9.1, 9.2, 9.3. The information transmitted by the receiver units 9.1, 9.2, 9.3 regarding the received radio signals, which can be assigned by the computer 11 unambiguously to the respective devices 4.1-4.11, 8 that are transmitting the radio signals with the aid of the database 12, in this case fully matches the respective devices previously determined as being in the neighbourhood of the receiver units 9.1, 9.2, 9.3. A corresponding comparison carried out by the computer 11 suggests that there is no fault in the supply network 1, since all the checkable devices 4.1-4.7, 4.9, 4.10 connected to the network are clearly active. If a radio signal could not be received from one of the said devices, it is basically possible to assume that the device concerned is deactivated, which in turn can represent an indication of a fault in the network.

A first case of a fault in the supply network 1 according to FIG. 1 is illustrated in FIG. 2a. The actual fault is marked as X, and fully interrupts the supply of power to the devices located behind the fault, as seen from the connecting point 2. The devices 4.1, 4.2, 4.3 and 4.4 are thus affected by the fault.

If the comparison described previously of the radio signals actually received by the receiver units 9.1, 9.2, 9.3 with those that ought to be received according to the database 12 is then carried out, the active and deactivated devices 4.1-4.11, 8 can be determined for each receiver unit 9.1, 9.2, 9.3.

It can thus be determined for the receiver unit 9.1 that the devices 4.3, 4.4, whose radio signals ought in principle to be received, are clearly deactivated, whereas the device 4.7 is still transmitting radio signals, and device 4.7 is thus active. With just this information it is possible to derive from the network topology—in an automated manner by the computer 11 where appropriate—that the fault presumably lies between the line branch 3.1 and the device 4.4.

The results of the other receiver units 9.2 and 9.3 can confirm this presumption. Since the receiver unit 9.3 continues to receive the radio signals of the devices 4.9 and 4.10, it can be presumed that the line is free from faults between the connecting point 2 and the device 4.9. The fact that no radio signals can be received from the device 4.6 does not, on the other hand, provide an indication of a fault in its supply line, since this device 4.6 in the state illustrated in FIG. 2a is switched off by the timer switch 7, and has thus been intentionally deactivated. Since appropriate information about the deactivation of the device 4.6 at certain times is stored in the database 12, the computer 11 can identify the absence of the radio signals of the device 4.6 as being in order, and not as a state indicating a network fault.

The receiver unit 9.2 can also no longer receive radio signals of the device 4.6, which however again, with reference to the information from the database 12, is not understood as a fault of the supply network 1. Since the receiver unit 9.2 continues not to receive any signals from the device 4.1, but only from the devices 4.2, 4.5 and 8, a fault in line 3, which leads from the line branch 3.1 to the device 4.1, is also indicated. Since it is known from the database 12 that the device 4.2 has an uninterruptible power supply, the possibility that the radio signals of this device 4.2 are incorrectly seen as an indication of a functioning power supply to the device 4.2 by the supply network 1 is avoided.

An alternative case of a fault in the supply network 1 according to FIG. 1 is illustrated in FIG. 2b. In this case, the fault marked as X occurs in the line between the devices 4.3 and 4.4.

The situation with regard to the fault of FIG. 2a is unchanged for the receiver units 9.2 and 9.3, for which reason reference is made to the explanations there.

In contrast to this fault described above however, the receiver unit 9.1 also still receives the radio signals of the device 4.4 in the fault according to FIG. 2b. Through the evaluation of the computer 11, as described in association with FIGS. 1 and 2b, it is thus possible to directly establish that the fault presumably lies in the line between device 4.3 and 4.4.

The radio signals transmitted by the devices 4.1-4.11, 8 are WLAN signals, in particular WLAN beacons, which can be received and evaluated without, for example, a receiver unit 9.1, 9.2, 9.3 having to be connected to the corresponding WLAN.

1. Method for the local delimitation of faults (X) in an electrical distribution network (1) with a receiver unit (9.1, 9.2, 9.3) comprising a position determination module and with a database (12) comprising position information regarding devices (4.1-4.11), connected to the distribution network (1), which transmit radio signals identifiable by the receiver unit (9.1, 9.2, 9.3) and assignable to the respective device (4.1-4.11), with the steps of:
a. determining the active devices (4.1-4.11) located in the neighbourhood of the receiver unit (9.1, 9.2, 9.3) using the identifiable radio signals transmitted by these devices (4.1-4.11) and assignable to the respective device (4.1-4.11);
b. determining the position of the receiver unit (9.1, 9.2, 9.3) through the position determination module;
c. determining, from the database, devices (4.1-4.11) located in the neighbourhood of the receiver unit (9.1, 9.2, 9.3) on the basis of the determined position of the receiver unit (9.1, 9.2, 9.3);
d. determining the deactivated devices (4.1-4.11) in the neighbourhood of the receiver unit (9.1, 9.2, 9.3) through comparison of the active devices (4.1-4.11) determined with the determined devices (4.1-4.11) located in the neighbourhood of the receiver unit (9.1, 9.2, 9.3); and
e. delimiting the fault in the distribution network by evaluating the position information of the active and deactivated devices (4.1-4.11).

2. Method according to claim 1,
characterized in that
the position information comprises particulars of the geographical position and/or the position in the network topology.

3. Method according to claim 1 or 2,
characterized in that
the database (12) comprising position information contains information about the time-dependent activation and deactivation of at least some of the devices (4.6) connected to the distribution network (1) and/or information about whether devices (4.2) connected to the distribution network (1) have an uninterruptible power supply (6).

4. Method according to one of the preceding claims,
characterized in that
the database (12) contains position information for devices (8) not connected to the distribution network (1) which transmit radio signals that are identifiable by the receiver unit (9.1, 9.2, 9.3) and assignable to the respective device (8).

5. Method according to one of the preceding claims,
characterized in that
the devices (4.1-4.11) connected to the distribution network (1) comprise the network operator's own devices, preferably electricity meters and/or distribution boxes.

6. Method according to one of the preceding claims,
characterized in that
the receiver unit (9.1, 9.2, 9.3) is an electricity meter or a mobile terminal, preferably a smartphone or a tablet.

7. Method according to claim 6,
characterized in that
the change in the charging process and/or the light impinging on a camera of the mobile telephone are taken into account in the delimitation of the fault in the distribution network (1) as additional information about the status of the distribution network (1) in the region of the receiver unit (9.1, 9.2, 9.3).

8. Method according to one of the preceding claims,
characterized in that
the database (12) is self-learning, and information relating to the connection to the distribution networks and/or an uninterruptible power supply (6) of individual devices (4.1-4.11) is preferably updated as required.

9. Method according to one of the preceding claims,
characterized in that
the position determination module is designed for determining the position of the receiver unit (9.1, 9.2, 9.3) through satellite navigation signals, through an evaluation of the radio signals identifiable by the receiver unit (9.1, 9.2, 9.3) and assignable to a device (4.1-4.11, 8) and/or through calling up a position stored in a memory.

10. Method according to one of the preceding claims,
characterized in that
the radio signals identifiable by the receiver unit (9.1, 9.2, 9.3) and assignable to a device (4.1-4.11, 8) are WLAN, Bluetooth, Zigbee, Z-Wave and/or EnOcean signals.

11. Arrangement for the local delimitation of faults (X) in an electrical distribution network (1) comprising a receiver unit (9.1, 9.2, 9.3) with a position determination module, a database (12) comprising position information about devices (4.1-4.11), connected to the distribution network (1), which transmit radio signals identifiable by the receiver unit (9.1, 9.2, 9.3) and assignable to the respective device (4.1-4.11), and a computer (11), characterized in that
the computer (11) is designed to determine from the database (12), with reference to the position determined by the position determination module of the receiver unit (9.1, 9.2, 9.3), devices located in the neighbourhood of the receiver unit (9.1, 9.2, 9.3), and to check, with reference to the radio signals received by the receiver unit (9.1, 9.2, 9.3), which of the devices determined in this way are active and which of the devices determined in this way are deactivated.

12. Arrangement according to claim 11,
characterized in that
the arrangement is designed to carry out a method according to one of claims 1-10.
